(19) United States
(12) Patent Application Publication
(10) Pub. No.: US 2006/0239474 A1
(43) Pub. Date: Oct. 26, 2006

(54) Gigbox: a music mini-studio

(76) Inventor: Stephen Simms, Miami, FL (US)

Correspondence Address: Wilson Daniel Swayze, Jr, 3804 Clearwater Ct, Plano, TX, 75025, US

(21) Appl. No.: 11/110,544

(22) Filed: Apr. 20, 2005

(51) Int. Cl. H03G 5/00

(52) U.S. Cl. 381/103

(57) ABSTRACT

A portable device for combining the sounds from at least two users includes a first input for inputting first sounds from a first user, a second input for inputting second sounds from a second user, a circuit to combine the first sounds from the first input and the second sounds from the second input to generate a combined signal and an output circuit to output the combined signal so that the first user and the second user can listen to the combined signal without disturbing other non-musicians.

### BACKGROUND

Musicians from beginners to experts practice their music almost on a daily basis. This need for practice exists whether or not the musicians are at home or away. This is especially true for musicians who play together in a band or orchestra. This need for practice conflicts with the interest of non-musicians when the musicians practice their music away from the conventional, room-size studio. More particularly, when the musicians practice either at home or on the road, there is a need not to disturb the non-musicians with the sound of the musician's music.

Also, there is a need for musicians to equalize their music in order to eliminate undesirable sounds and to enhance the more desirable music.

### SUMMARY

The present invention provides an apparatus for a musician to practice his/her music with other musicians without the need of the conventional room-size studio or the associated expensive and bulky equipment.

Additionally, the apparatus of the present invention provides a means for musicians to hold a silent practice session by using headphones and to record the silent practice sessions so that the resulting music from the silent practice sessions are retained for later use. These silent practice sessions are advantageous for use in a hotel room, a cramped apartment, or any other area where a silent practice session is desirable.

The present invention allows the user to equalize the music input so that undesirable sounds can be eliminated or minimized while the desirable sounds can be enhanced.

The present invention provides the ability to record and create well produced recordings for example on compact disc or cassette tapes. This allows the musicians to audition for most record labels. These recordings can be edited and enhanced to generate a nearly perfect song or track, saving thousands of dollars in studio editing time.

The present invention allows a plurality of users to input music into a common portable apparatus so that the inputted music can be heard by all of the users, and other users can input additional music to be combined with all the other inputted music and the resulting combined music can be recorded onto a recording medium. Additionally, the inputted music can be equalized so that undesirable music can be eliminated or reduced and desirable music can be enhanced by the user.

The number of users could vary depending upon the model of the apparatus.

The apparatus of the present invention is portable, relatively lightweight, and includes a handle for carrying the apparatus from one location to another.

### BRIEF DESCRIPTION OF THE DRAWING

FIG. 1 illustrates a Gigbox or apparatus of the present invention;

FIG. 2 illustrates a headphone or WiFi apparatus headphone;

FIG. 3 illustrates a circuit diagram to be used with the present invention.

### DETAILED DESCRIPTION

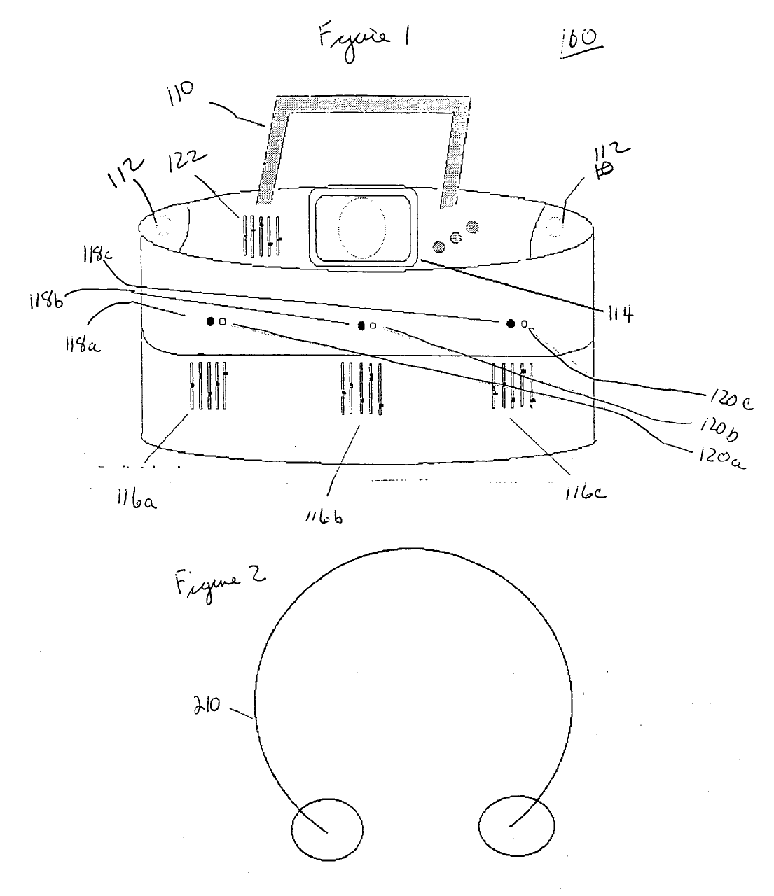

FIG. 1 illustrates a Gigbox: a music mini-studio constructed in accordance with the present invention. The Gigbox 100 includes a grip handle 110 to allow the Gigbox 100 to be portable and to be easily carried from one location to another location. The Gigbox 100 also includes speakers 112 shown on two sides of the upper portion of the Gigbox 100 to output the music or sounds from the Gigbox 100. Additionally, shown in FIG. 1 is a recording device 114 to record the music or sounds output from the Gigbox 100. The recording device 114 is shown in FIG. 1 in the top portion of the Gigbox 100 which could be both a CD recorder and a tape recorder. Other locations for the recording device 114 are within the scope of the present invention. Along the side of the Gigbox 100 are individual equalizers shown as equalizers 116a, 116b, and 116c. Taking equalizer 116a as an example, equalizer 116a equalizes the input music from the first user. In a similar fashion, equalizer 116b equalizes the input music from the second user. As a result of equalizer 116a, the first user can attenuate or reduce undesirable music such as low-frequency music from the music input to the Gigbox 100 or alternatively enhanced the desired music input to the Gigbox 100 such as enhancing the high-frequency music. Each user playing a different tune or vocalizing inputs the music or song into the respective input for example input socket 118a or input socket 118b. The music or song from each user is equalized and then combined and the output of the combined music is output to the respective output socket 120a and 120b. In this manner, the first and the second user can hear the effect of playing together. Furthermore, the results can be saved both on a tape recorder or compact disc recorder.

FIG. 1 additionally shows the inputs to the Gigbox 100. The Gigbox 100 includes a input socket 118a to accept input music from an instrument such as electric guitars, drum machines, keyboards, microphones or any such instrument which has an appropriate output plug. The Gigbox 100 includes output socket 120a to output the music from the Gigbox 100.

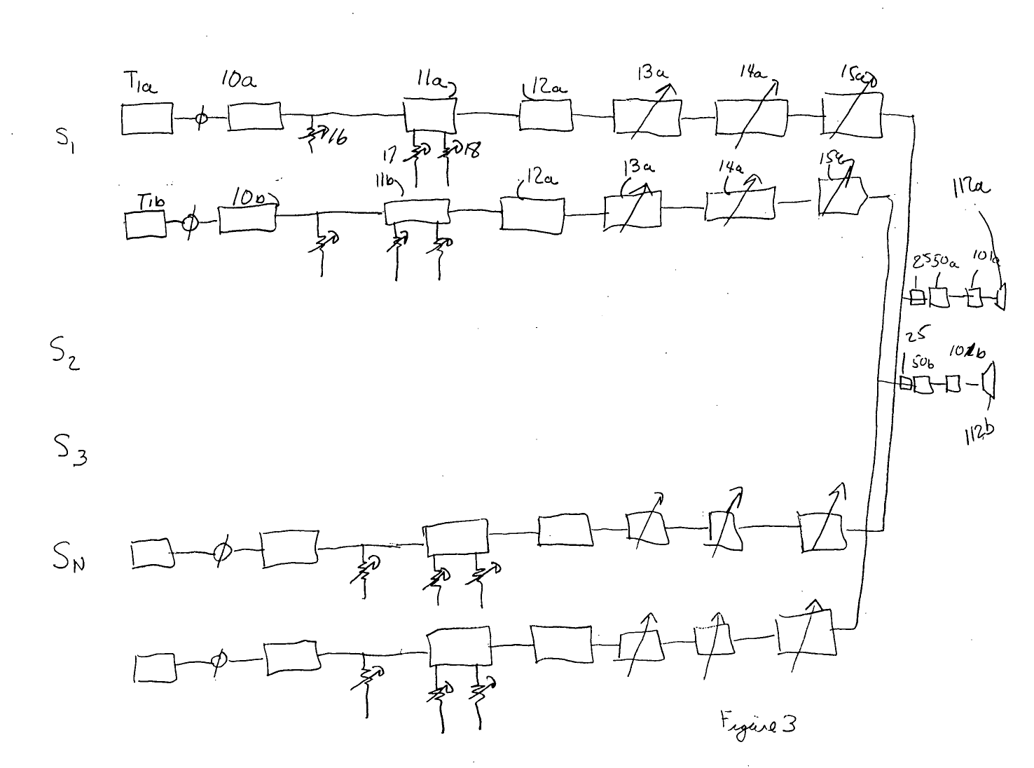

FIG. 2 illustrates headphones 210 which could be WiFi headphones or wired headphones for the user to listen to the output music from the Gigbox 100. Typically, the headphones 210 would be plugged in to the output socket 120a for example for the first user. Another user would plug in to output socket 120b.

The Gigbox 100 provides a portable way of practicing music while the musicians are away from the conventional room-size studio, and the Gigbox 100 eliminates the need for musicians, from a beginner to an expert, to carry expensive and bulky equipment from location to location. Users of the Gigbox 100 can conduct virtually silent practice sessions anywhere. The sessions can be held virtually anywhere and advantageously where creating high volumes of sounds is unacceptable for example small hotel rooms and apartments, or tiny practice chambers. Furthermore, the Gigbox 100 allows the user to individually equalize the input sounds to allow the various users independent equalization to provide high-quality, ear pleasing sounds. Additionally, the Gigbox 100 allows the user to make balanced, well produce recordings on compact disc or/and cassette tapes. This allows the various users/musicians to create demo tapes and demo CDs which are important in an obtaining an audition from record labels. These recordings can be used to edit and enhance songs or music tracks to a perfect condition and it could save studio editing time.

The present invention could be made to accommodate various numbers of users for example 3, 5 or 8 users. Consequently, the device could be tailored to the user's needs, intentions and their budgets. Ideally, the Gigbox 100 would be lightweight for example 20 to 25 pounds. By virtue of the fact that the user can plug in an amplifier into for example input 118a and plug in their headphones into output 120a allows the user to be ready to make a professional recording. The Gigbox 100 could be modified for specially made microphones and could jack in woodwind, string, and standard percussion instruments. The present invention could include a tape recorder and a compact disc recorder to play the music on the tape recorder and use the compact disc recorder to record the music on a CD in order to make a more permanent recording.

The device of the present invention combines the functions of a compact disc recorder, speakers, equalizers and a sound mixer which is the main equalizer to provide a Gigbox 100. The present invention utilizes current technology and adds miniaturization and combination to provide the Gigbox 100.

The function of the CD player should use a high-quality compact disc recorder (CDR) to be able to withstand repeated use and would includes the functions of record, erase, playback, skip forward to a track, reverse to a track and stop/eject. The tape recorder would have the same functions as described above; however, the function of erase may not be needed because the user could rewind the tape and record over any mistakes or unwanted selections. Both recording systems namely the tape recorder and the CD recorder could be played through the high Fidelity speakers shown on the top of this Gigbox 100. The master equalizer which includes a volume knob and possibly a bass boost button to allow the user to adjust the timbre, tone, balance, and overall quality of the sound.

Furthermore, the Gigbox 100 would allow a single user to sharpen their own vocal and instrumental performances, critique their own songs, tighten beats and raps, and just about any other function that they could do in a full-size music studio.

Turning now to FIG. 3, FIG. 3 illustrates the major electrical components of the gig box 100. It should be noted that the letter ‘a’ has been used to designate the apparatus having a mono version, and the letter b has been used to designate the apparatus with a stereo version. Additionally, the subscripts denote different channels for different users, namely S1 corresponds to a first user, S2 corresponds to the second user and Sn corresponds to the nth-user. Additionally, T1, T2 and Tn designate a number of transducers for example microphones playback heads etc. The transducer, for example T1, is connected to the preamplifier 10, and a tone regulating circuit 11 is connected to the output of the preamplifier 10. The operation of the tone regulation circuit 11 is controlled by potentiometers 17, 18. A potentiometer 16 is located upstream of the circuit 11 to control the volume of the signal coming out of the preamplifier 10. A voltage follower 12 is connected with the output of circuit 11 and has the function to isolate the upstream part of a circuit blocks 10 and 11 from the downstream part. The downstream part includes three band-separating active filters 13, 14, 15 respectively. The output of the band-separating active filters 13, 14, 15 from each respective source is connected to summer 50a to be summed and output to recorder 101a which could be a tape recorder or/and CD recorder to record the summed signal. Lastly, the output of the recorder is output to speaker 112. A master equalizer could be used to equalize the combined music and song prior to being output at the output socket 120a-120c.

The present invention has been described in terms of specific embodiments. Modification to the specific embodiments are well within the scope of the present invention without departing from the spirit of the invention.

1. A portable device for combining the sounds from at least two users, comprising:
a first input for inputting first sounds from a first user;
a second input for inputting second sounds from a second user;
a circuit to combine the first sounds from the first input and the second sounds from the second input to generate a combined signal;
an output circuit to output the combined signal so that the first user and the second user can listen to the combined signal without disturbing other non musicians.

2. A portable device for combining the sounds from at least two users as in claim 1, wherein said portable device includes a first equalizer being connected to said first input.

3. A portable device for combining the sounds from at least two users as in claim 1, wherein said portable device includes a second equalizer being connected to said second input.

4. A portable device for combining the sounds from at least two users as in claim 1, wherein said combined signal is equalized by a master equalizer.

5. A portable device for combining the sounds from at least two users as in claim 1, wherein said output circuit is connected to a headphone.

6. A portable device for combining the sounds from at least two users as in claim 1, wherein said output circuit is connected to a WiFi headphone.

7. A portable device for combining the sounds from at least two users as in claim 1, wherein said output circuit is connected to a tape recorder.

8. A portable device for combining the sounds from at least two users as in claim 1, wherein said output circuit is connected to a CD recorder.

9. A method for using a portable device for combining the sounds from at least two users, comprising the steps of:
inputting first sounds from a first user;
inputting second sounds from a second user;
combining the first sounds from the first input and the second sounds from the second input to generate a combined signal;
outputting the combined signal so that the first user and the second user can listen to the combined signal without disturbing other non musicians.

10. A method for using a portable device for combining the sounds from at least two users as in claim 9, wherein said method includes the step of equalizing the first sounds.

11. A method for using a portable device for combining the sounds from at least two users as in claim 9, wherein said method includes the step of equalizing the second sounds.

12. A method for using a portable device for combining the sounds from at least two users as in claim 9, wherein the method includes the step of equalizing the combined signal.

13. A method for using a portable device for combining the sounds from at least two users as in claim 9, wherein said method includes the step of using a headphone to listen to the combined signal.

14. A method for using a portable device for combining the sounds from at least two users as in claim 9, wherein said that includes the step of using a WiFi headphone to listen to the combined signal.

15. A method for using a portable device for combining the sounds from at least two users as in claim 9, wherein said output circuit is connected to a tape recorder.

16. A method for using a portable device for combining the sounds from at least two users as in claim 9, wherein said output circuit is connected to a CD recorder.
